(19) United States
(12) Patent Application Publication
(10) Pub. No.: US 2024/0110068 A1
(43) Pub. Date: Apr. 4, 2024

(54) Parylene-in-Oil Hydrophobic Coating

(71) Applicant: California Institute of Technology, Pasadena, CA (US)

(72) Inventors: Yu-Chong Tai, Pasadena, CA (US); Kuang-Ming Shang, Pasadena, CA (US); Haixu Shen, Pasadena, CA (US); Ningxuan Dai, Pasadena, CA (US); David Q. Kong, Cambridge, MA (US)

(73) Assignee: California Institute of Technology, Pasadena, CA (US)

(21) Appl. No.: 18/479,286

(22) Filed: Oct. 2, 2023

Related U.S. Application Data
(60) Provisional application No. 63/412,675, filed on Oct. 3, 2022.
(60) Provisional application No. 63/412,683, filed on Oct. 3, 2022.

(51) Int. Cl. C09D 5/16; B05D 1/00; B05D 3/02; B05D 3/14; C09D 5/08; C09D 125/02; C09D 191/00

(52) U.S. Cl. CPC C09D 5/1681; B05D 1/60; B05D 3/0218; B05D 3/148; C09D 5/086; C09D 125/02; C09D 191/00; B05D 2350/60; B05D 2507/00

(57) ABSTRACT

A thin oil film having parylene irregular dendritic-like columns extending from one side to another exhibits hydrophobic properties that can be used as a corrosion resistant coating or water-repellant, biofouling resistant surface. This parylene-in-oil layer can be paired with an adjacent layer of solid parylene that it overlays or underlays. The solid parylene cross polymerizes with the parylene dendrites, keeping them in place as well as the oil film. The parylene dendrites are fabricated by chemical vapor deposition (CVD) of parylene over the oil layer, the dendrites self-forming from the bottom to the top. Continued CVD over the dendrites can produce a top layer of solid parylene. Etching the solid parylene away can result in a water repellant, anti-biofouling surface.

### CROSS-REFERENCES TO RELATED APPLICATIONS

This application claims the benefit of U.S. Provisional Application No. 63/412,675, filed Oct. 3, 2022 and U.S. Provisional Application No. 63/412,683, filed Oct. 3, 2022, which are hereby incorporated by reference in their entireties for all purposes.

### STATEMENT AS TO RIGHTS TO INVENTIONS MADE UNDER FEDERALLY SPONSORED RESEARCH AND DEVELOPMENT

Not applicable.

### BACKGROUND

### 1. Field of the Art

Embodiments of the present invention generally relate to materials and methods for coating medical and other devices, the materials comprising different phases. Specifically, embodiments relate to hydrophobic coatings in which an oil film has irregular, dendritic columns made of parylene that extend from one side of the film to another, one side of which is a solid sheet of parylene.

### 2. Description of the Related Art

Parylene is a generic name for members of a series of poly(p-xylylene) polymers. Parylene polymer is known to excel as a dielectric and as a water vapor barrier without being toxic. Having been commercialized in the 1960s, parylene has found widespread use in the electronics, automotive, aerospace, medical, and other industries. It generally has preferable chemical vapor depositing attributes in that it can be deposited in extremely thin layers that are relatively strong and essentially pinhole-free.

Parylene N is the basic member of the parylene series. It is commonly derived from [2.2]paracyclophane, which can be synthesized from p-xylene. Parylene N is typically a completely linear, highly crystalline material.

Parylene C, which has one chlorine group per repeat unit, is another of the series. It is typically produced from the same dimer as parylene N but has a chlorine atom substituted for one of the aromatic hydrogen atoms. Its ease of use and especially well-mannered chemical vapor deposition characteristics make it sell suited a conformal coating on printed circuit boards and as a structure in nanofabricated devices. Its demonstrated bio-compatibility as a United States Pharmacopeial Convention (USP) Class VI biocompatible polymer makes it suitable for medical devices.

Parylene D, which has two chlorine groups per repeat unit, is another common parylene of the series. Although it has better diffusion characteristics than parylene C, parylene D generally deposits less uniformly than parylene C.

Parylene AF-4, with the alpha hydrogen atoms of the N dimer replaced with fluorine, is another parylene of the series. Parylene AF-4 is also known as Parylene SF when manufactured by Kisco Conformal Coating, LLC of California (a subsidiary of Kisco Ltd. of Japan) or PARYLENE HT® when manufactured by Specialty Coating Systems, Inc. of Indianapolis, Indiana.

Other parylenes, such as parylene VT-4, parylene A, parylene AM, and parylene X, are known in the art and are used for specialized products in industry.

Fundamental aspects of parylene N and parylene C are detailed in P. Kramer et al., “Polymerization of Para-Xylylene Derivatives (Parylene Polymerization). I. Deposition Kinetics for Parylene N and Parylene C,” Journal of Polymer Science: Polymer Chemistry Edition, Vol. 22 (1984), pp. 475-491. This journal article is hereby incorporated by reference it its entirety for all purposes.

Fundamental aspects of parylene X are detailed in J. Senkevich et al., “Thermomechanical Properties of Parylene X, A Room-Temperature Chemical Vapor Depositable Crosslinkable Polymer,” Chem. Vap. Deposition, 2007, 13, pp. 55-59. This journal article is hereby incorporated by reference it its entirety for all purposes.

To apply parylene to a surface, it is often deposited in a vacuum chamber by way of chemical vapor deposition (CVD). First, a solid parylene dimer, typically a powder, is heat vaporized into a gaseous state. Second, the vaporized dimer is subject to pyrolysis with further heat in order to separate the dimer into monomers. Third, the monomer in a vapor passes into a deposition chamber where a workpiece is located. The workpiece is often at room temperature. The monomers join together, polymerizing molecule by molecule into a parylene dimer, and conformally coats the workpiece. The workpiece is then removed from the vacuum and any masking removed.

This process above is used for parylene C for biomedical applications, such as coating portions of implants. However, parylene C's chemical inertness results in poor adhesion between it and underlying materials, especially applications that require robustness and long-term reliability

While several approaches have been investigated to enhance adhesion, including mechanically roughening the surfaces with plasma, chemically treating the surfaces with adhesion promotors (e.g., A-174 silane), and subsequent low-temperature annealing in a vacuum chamber, most of these approaches only address parylene adhesion under dry conditions.

Under wet conditions, which are a clinical reality, long-term parylene adhesion remains an engineering challenge because parylene, as a polymer, is subject to water vapor permeation. Once at the interface between parylene and the underlying surface of the implant, water vapor can condense to water. Water breaks the adhesion and causes delamination of the parylene. If there are metallic or other susceptible materials in the implant, the water prompts corrosion and potential malfunction. Stagnant water pockets, even miniscule ones, can also lead to biofouling.

There is a need in the art to improve long lasting parylene adhesion in bioimplants and other wet-environment applications.

### BRIEF SUMMARY

Generally, a thin film of oil with parylene dendrites that extend from one face of the film to the other acts as a hydrophobic coating. Dendrites have the appearance of irregular columns, like stalactites and stalagmites that have met to form stalagnates. This parylene-in-oil coating can be applied on its own or paired with a layer of solid parylene on one side to apply to surfaces. If the parylene-in-oil thin film directly touches a device surface and the solid parylene layer is on top of the thin film, then the coating acts to prevent corrosion. The enclosed oil prevents water condensation against the surface. If the parylene-in-oil thin film sits atop an underlying layer of parylene that conformally coats a surface, then the parylene-in-oil acts as a water shedding, anti-biofouling surface.

The parylene-in-oil layer is largely manufactured by pouring a thin layer of oil on a substrate and then depositing, by chemical vapor deposition, parylene over the oil. The parylene monomers diffuse into the oil, combine into dimers, and somewhat self-organize into tiny, irregular stalagmites with oil between them. The stalagmites stack up with more deposited parylene until they reach the surface of the oil film, forming dendrites. Continued deposition on top of the oil and dendrites forms a solid layer of parylene over them, integrally connecting with the dendrites.

If the substrate at the bottom of the oil is the surface of a device, such as a bioimplant or marine electronics, then the surface is protected from water.

If the parylene-in-oil film is over a parylene substrate, and the dendrites cross polymerize and attach themselves to the substrate, then the top layer of parylene can be chemically etched away to reveal the tops of the dendrites and oil between. The oil, and perhaps the spacing of the tops of the dendrites, is extremely effective in beading up water, essentially superhydrophobic.

Some embodiments of the invention are related to a composition of matter for hydrophobic coatings, the composition of matter including a film of liquid oil having a thickness less-than-or-equal-to 10 microns (μm), and parylene dendrites extending through the oil film from one surface of the film to an opposing surface of the film.

Oil film thickness between 1 nanometer and 1 centimeter are envisioned.

The oil can have a vapor pressure of less than 1.333 kilopascal at 25° C. The oil can be selected from the biocompatible (and optionally biodegradable) group consisting of silicone oil, fluorinated oil, vegetable oil, and natural human fat oil. The oil can be silicone oil with a viscosity greater-than-or-equal-to 10 centistokes (cSt), and it may have a film thickness between 0.5 μm and 10 μm.

The parylene can be selected from the group consisting of parylene C, parylene D, parylene F, parylene AF-4, and parylene N.

The composition of matter can include a layer of solid parylene integrally formed with the parylene dendrites.

Some embodiments include an apparatus with a biofouling-resistant coating, the apparatus including a device, such as a medical or marine device, and the composition of matter disclosed above, in which the layer of solid parylene is conformally coated on a surface of the device and the film of liquid oil with parylene dendrites faces outward.

Some embodiments include an apparatus with a corrosion resistant coating, the apparatus including a device, and the composition of matter disclosed above, in which the film of liquid oil with parylene dendrites is conformally coated on a surface of the device and the layer of solid parylene faces outward. The surface of the device can include metal traces or metal components for an electrical circuit.

Some embodiments are related to a method of producing a coating that bestows corrosion-resistance to a surface, the method including providing a surface to be protected, applying a film of liquid oil to the surface, the film having a thickness less-than-or-equal-to 10 microns (μm), depositing, by chemical vapor deposition (CVD) in a vacuum chamber, parylene over the oil film, the deposited parylene growing dendrites from the surface, at the bottom of the oil film, through the oil to a top of the oil film, and laying, by further CVD, a solid layer of parylene on top of the oil film and dendrites, the solid layer integrally connecting with the dendrites.

The oil can be selected from the biocompatible (and optionally biodegradable) group consisting of silicone oil, fluorinated oil, vegetable oil, and natural human fat oil. The oil can be silicone oil with a viscosity greater-than-or-equal-to 10 centistokes (cSt). The surface can include metal traces or metal components for an electrical circuit.

The applying can include reducing the film thickness to between 1 μm and 2 μm. One can spin the surface in order to reduce the film thickness to less-than-or-equal-to 10 μm. One can silanize the surface before applying the film of liquid oil. The oil can be initially diluted in a solvent, and the method can further include heating the film of liquid oil to evaporate the solvent after the applying. The parylene can be selected from the group consisting of parylene C, parylene D, parylene F, parylene AF-4, and parylene N.

Some embodiments are related to a method of producing a fluid-repellant, biofouling-resistant surface, the method including providing a device having a conformal coating of parylene, applying a film of liquid oil to the coating, the film having a thickness less-than-or-equal-to 10 microns (μm), growing, by chemical vapor deposition (CVD) in a vacuum chamber, parylene dendrites from the surface, through the oil, to a top of the film, forming, by further CVD, a solid layer of parylene on top of the oil film, the solid layer integrally connected with the dendrites, and treating, with oxygen or other plasma, the solid layer sufficient to ablate the solid layer away and expose tops of the parylene dendrites.

### BRIEF DESCRIPTION OF THE DRAWINGS

FIG. 1 is cross section view of a parylene-in-oil hydrophobic coating in isolation in accordance with an embodiment.

FIG. 2 is a cross section view of a corrosion resistant coating in accordance with an embodiment.

FIG. 3 is an electron microscope (SEM) image of a cross section of a corrosion resistant coating with a 9.93 μm oil film thickness.

FIG. 4 is an SEM image of a cross section of a corrosion resistant coating with a 0.84 μm oil film thickness.

FIG. 5A illustrates a bare electronic device before coating in accordance with an embodiment.

FIG. 5B illustrates the device of FIG. 5A being coated with a film of oil.

FIG. 5C illustrates the oil film of FIG. 5B having its thickness reduced.

FIG. 5D illustrates chemical vapor deposition (CVD) of parylene over the oil film of FIG. 5C.

FIG. 5E illustrates dendrites grown to the top of the oil film from CVD of FIG. 5D.

FIG. 5F illustrates a layer of solid parylene deposited over the dendrites of FIG. 5E.

FIG. 6 is a flowchart illustrating a process in accordance with an embodiment.

FIG. 7 is a cross section view of a water-repellant coating in accordance with an embodiment.

FIG. 8 is an SEM micrograph of a top of a water-repellant coating in accordance with an embodiment.

FIG. 9 is an SEM micrograph of a cross section of a water-repellant coating in accordance with an embodiment.

FIG. 10A illustrates a conformally coated electronic device before further coating in accordance with an embodiment.

FIG. 10B illustrates the device of FIG. 10A being coated with a film of oil.

FIG. 10C illustrates CVD of parylene over the oil film of FIG. 10B.

FIG. 10D illustrates dendrites grown to the top of the oil film from the CVD process of FIG. 10C.

FIG. 10E illustrates a layer of solid parylene deposited over the oil film and dendrites of FIG. 10D.

FIG. 10F illustrates etching away the layer of solid parylene of FIG. 10E.

FIG. 11 is a flowchart illustrating a process in accordance with an embodiment.

FIG. 12 is a micrograph of an E. coli biofilm covering a coating of parylene of the prior art.

FIG. 13 is a micrograph of an almost nonexistent E. coli biofilm on a water repellant, biofouling resistant coating in accordance with an embodiment.

### DETAILED DESCRIPTION

Coatings that include a thin layer of oil through which microscopic, regularly spaced columns or irregular dendritic columns of parylene pass can be used for corrosion resistance or biofouling resistance, among other uses. This parylene-in-oil layer is hydrophobic, so much so that it tends to prevent water vapor from condensing into liquid water. The oil can be in liquid form and held in place by surface forces to the parylene columns and a sheet of solid parylene that is integrally formed with the dendrites.

When the parylene-in-oil faces a device surface, it prevents water condensation on the surface and thus prevents water-based electrochemical corrosion. When the parylene-in-oil faces outward, it sheds water and helps prevent biological cells from attaching, reproducting, or thriving.

Manufacturing dendritic columns of parylene does not require photolithography or arrays of masking. They can be produced at a macro scales by chemical vapor deposition of parylene over a thin layer of non-evaporative oil in a vacuum chamber. The parylene may or may not be denser than the oil to grow the dendrites.

A material is considered “evaporative” if its partial pressure is about 10-100 torr (1.333-13.33 kilopascals), or as otherwise known in the art.

A “dendrite” is a treelike branching structure or simple stalagnate-like column, or as otherwise known in the art, and it is typically irregular in form. Dendrites form when parylene is chemical vapor deposited over film of oil, as parylene tends to clump together and grow stalagmite-like structures from the bottom up.

A “stalagnate” is somewhat of a portmanteau of stalactite and stalagmite,

which sometimes meet in underground caves to form a column. The word describes the irregular, natural appearance of a column.

“Corrosion resistance” includes water-based electrochemical corrosion resistance or as otherwise known in the art.

“Biofouling resistance” includes properties that deter biological cell adhesion, cell growth, or cell multiplication, or the adherence of products of cell life, or as otherwise known in the art.

“SLIPS” is a slippery liquid-infused porous surface, or as otherwise known in the art.

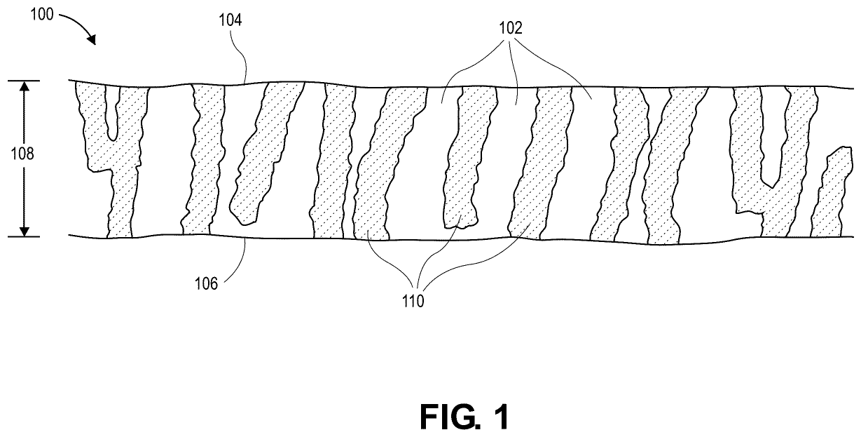

FIG. 1 is cross section view of parylene-in-oil hydrophobic coating 100 in isolation. Oil film 102 has thickness 108, typically less-than-or-equal-to 10 microns (μm), defined by top surface 104 and opposing, bottom surface 106. Thicknesses between 0.5 and 10 μm work well for silicone oils.

The oil can be any oil that will not be too evaporative in a vacuum chamber within which the parylene is deposited. For example, the oil should have a vapor pressure less than 10 torr (1.333 kilopascals) at standard room temperature (25° C.). The oil may or may not be less dense than solid parylene (mass density=1.289).

The viscosity of the oil may be chosen from a wide range to achieve a preferred thickness of the final oil layer. Viscosities greater-than-or-equal-to 10 centistokes (cSt) work well for spin coating where the spin speed in revolutions per minute may guide the actual thickness.

For human and animal implants, the oil is preferable biocompatible, such as silicone oil, fluorinated oil, vegetable oil, and natural human or animal fat oil. The oil may be selected to be biodegradable for certain applications, such as those that need to be flushed from the human body.

Oil 102 surrounds parylene dendrites 110, some of which extend through oil film 102 from surface 104 to opposing surface 106. Some dendrites are branched instead of columnar. Not all dendrites extend from surface to surface, as shown in the figure.

When the dendrites extend to a surface against which there is a layer of solid (bulk) parylene, they may cross polymerize with the solid parylene and be held in place and orientation.

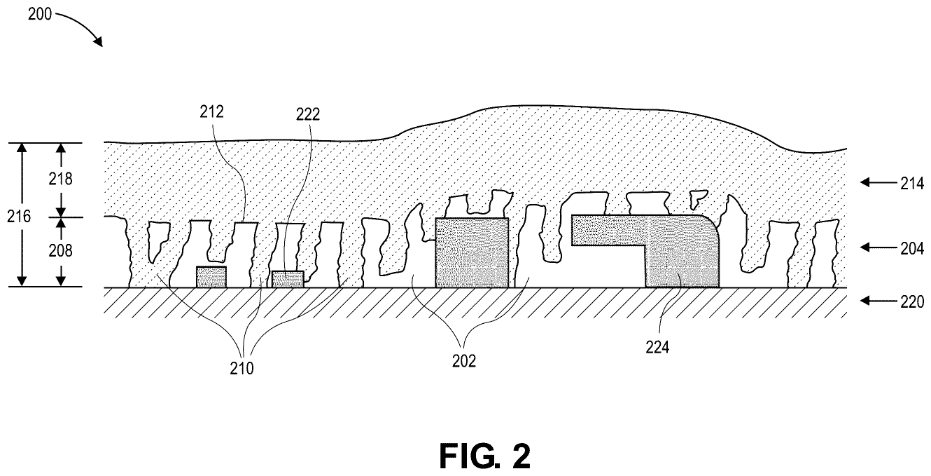

FIG. 2 is a cross section view of corrosion resistant coating 200 over device 220. Device 220 has metal traces 222, which may or may not be individually insulated, and electronics components 224.

Oil film 202 in parylene-in-oil layer 204 has thickness 208, typically less-than-or-equal-to 10 μm. Solid parylene layer 214 has thickness 218. It can be said that the thicknesses of the layers are defined where they meet at interface 212, which was the top of the oil film during deposition of the parylene. The combined thicknesses of parylene-in-oil layer 204 and solid parylene layer 214 is coating thickness 216.

Dendrites 210, surrounded by oil 202, extend from the device surface 220, at the bottom of the oil film layer 204, through oil 202 to the top of the oil film layer 204, which is interface 212. Some dendrites do not extend all of the way through the oil film, and some branch off. The dendrites that extend all of the way from solid parylene layer 214 to device 220 are what adheres coating 200 to the device. A smaller thickness allows more adhering dendrites and greater adhesion strength, at least initially.

The hydrophobic oil prevents water vapor, which inevitably permeates through the solid polymer to the device, from condensing to liquid water. That is, parylene-in-oil film 204 is thermodynamically favorable for preventing water condensation around the surface, traces, and electrical components. By preventing liquid water from forming, the parylene-in-oil film 204 helps prevent water-based corrosion on electrical traces 222 and electronic components 224 over time. It also prevents delamination of overall coating 200 from device 220, whether from freeze-thaw-boil cycles or from wayward cells multiplying and pushing the laminate away from the device's surface. A greater oil thickness may be better suited to repel water, or at least able to lose more oil and still function.

In any case, the parylene-in-oil layer against the surface, covered by a solid parylene layer, serves as a corrosion resistant coating for wet environments, such as in a human body, ocean, or humid environments. It may also prevent ice formation in seals and O-rings.

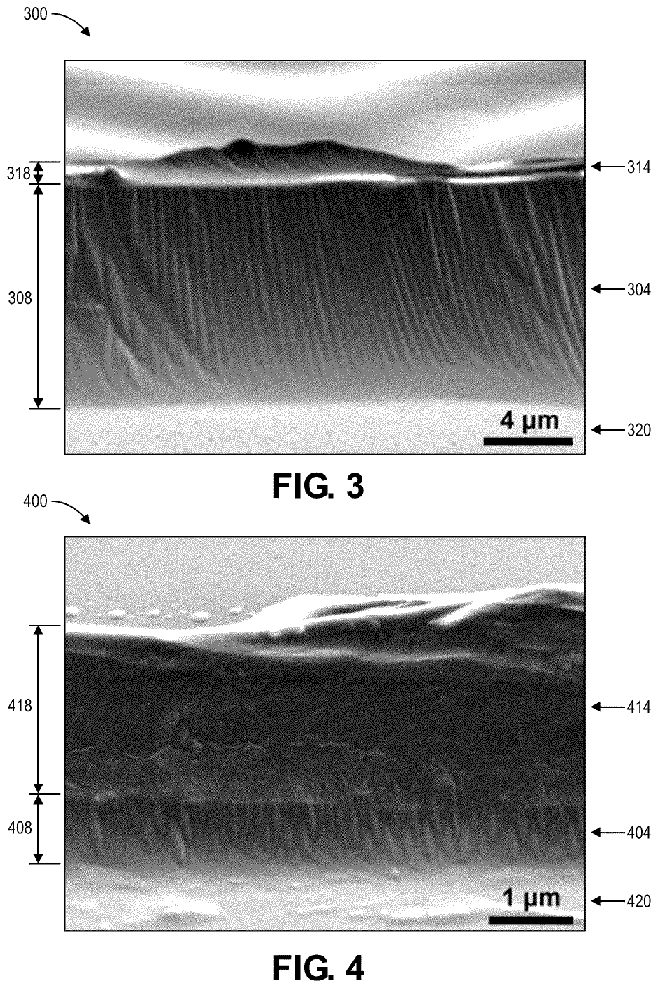

FIGS. 3-4 are scanning electron microscope (SEM) micrographs of cross sections of corrosion resistant coatings having 9.93 μm and 0.84 μm silicone oil film thicknesses, respectively. After a 2-μm parylene C deposition over oil film, the parylene-in-oil coatings were frozen in liquid nitrogen to preserve their structural integrity, diced, and imaged under SEM. Both cases comprise a solid parylene C layer on top and a parylene-in-oil mixed layer on the bottom. The top layer automatically provides excellent mechanical sealing for the underneath stalactite-like parylene-in-oil structures, which encapsulates the silicone oil.

In FIG. 3, coating 300 includes solid layer of parylene 314 having thickness 318 and parylene-in-oil layer 304 having thickness 308. Coating 300 covers glass substrate 320.

In FIG. 4, coating 400 includes solid layer of parylene 414 having thickness 418 and parylene-in-oil layer 404 having thickness 408. Coating 400 covers glass substrate 420.

As demonstrated in the SEM micrographs, the silicone oil thickness affects the cross-sectional morphologies of parylene-in-oil composites. The bottom parylene-in-oil layers exhibit slightly different morphologies as the oil thickness varies. When the silicone oil is thin, such as in FIG. 4, the volume ratio of oil and parylene is relatively uniform across the composite film. However, when the silicone oil becomes thicker, such as in FIG. 3, fewer parylene monomers are able to reach to, polymerize at, and form bonding with the bottom substrate. This phenomenon is observed in FIG. 3, where the silicone oil is the primary composition near the underlying substrate 320. Although the ability to prevent water permeation is superior when silicone oil is thicker, less parylene bonding to the substrate will weaken the adhesion strength under thicker oil conditions.

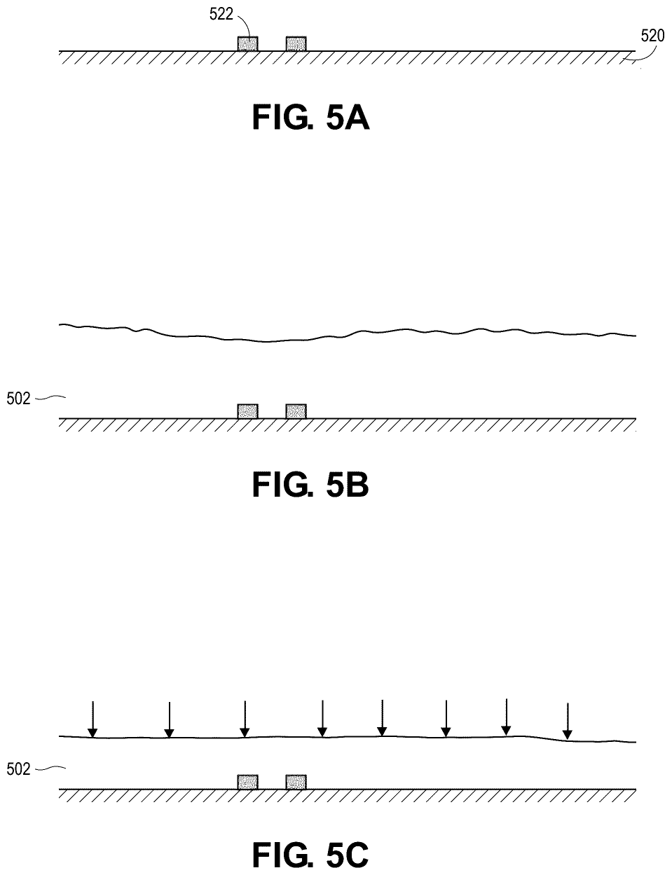

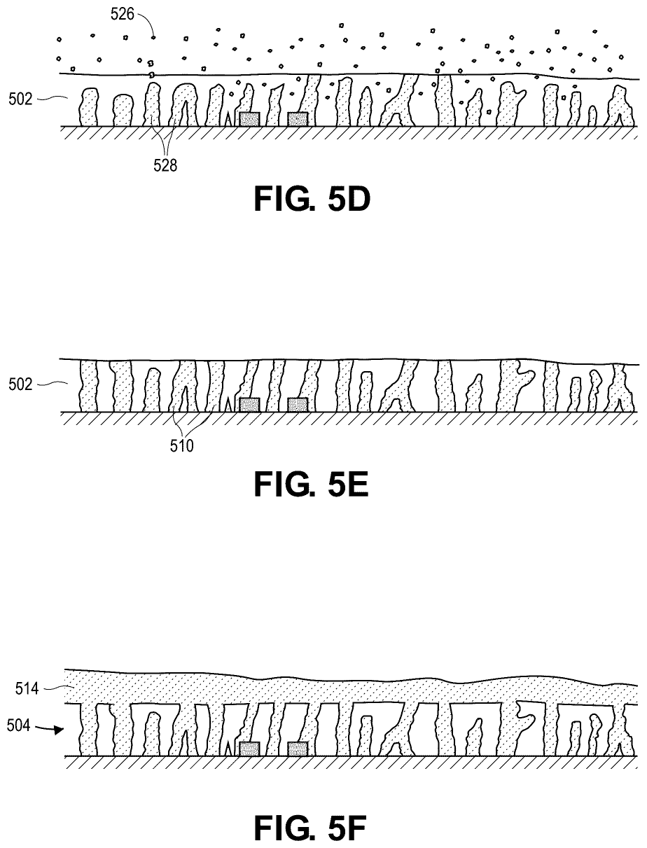

FIGS. 5A-5F illustrate the manufacture of a corrosion resistant coating over an electronic device.

In FIG. 5A, surface of device 520 is shown with metal electrical traces 522. In FIG. 5B, oil 502 is poured onto the device. In FIG. 5C, oil film 502 is reduced in thickness to a predetermined thickness.

In FIG. 5D, parylene C is deposited, by chemical vapor deposition in a vacuum chamber, over oil film 502. Parylene monomers 526 pass into the deposition chamber and diffuse into liquid oil 502. As more and more monomers diffuse into the oil, they meet each other and react to become dimers and polymerized parylene. This diffusion-reaction process does not depend substantially on the density or size of the monomer, so denser and lighter oils work fine.

The deposited parylene exhibits a phenomenon in which it essentially self-organizes to begin to grow inchoate dendrites 528 from the surface up through the oil. The dendrites can grow from the flat substrate, on top of the traces 522 (see FIG. 5A), or from the top of other components (not shown). In FIG. 5E, some parylene dendrites 510 have grown all the way to the top of oil film 502. CVD may stop temporarily at this point, or it may keep going continuously.

In FIG. 5F, solid parylene layer 514 is laid, by CVD, on top of parylene-in-oil layer 504 to a preferred thickness. The solid layer thickness may be relatively thin, like that in FIG. 3, or relatively thick, like that in FIG. 4.

As seen in the figure, the resulting product has a cross section much like that shown in FIG. 2. The hydrophobic parylene-in-oil layer 504 stays directly adjacent the device, and solid parylene layer 514 above it seals the parylene-in-oil layer 502 in place, protecting it from the elements.

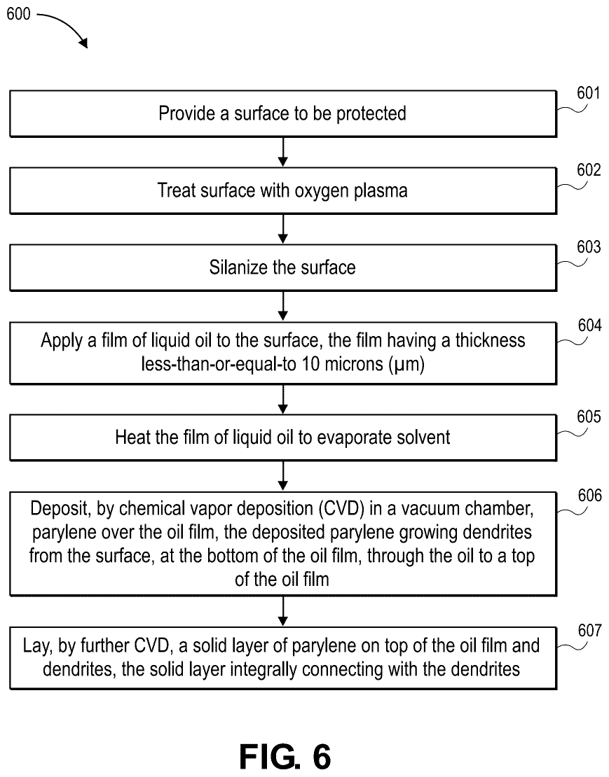

FIG. 6 is a flowchart illustrating process 600 in accordance with an embodiment. In operation 601, a surface to be protected is provided. In operation 602, the surface is treated with oxygen plasma for descumming and to remove impurities. In operation 603, the surface is silanized. For example, the workpiece surface can be submerged in a 0.5% (volume/volume) A-174 solution using a 1:1 deionized water, isopropyl alcohol solvent. In operation 604, a film of liquid oil is applied to the surface, the film having a thickness less-than-or-equal-to 10 microns. In operation 605, the film of liquid oil is heated in order to evaporate any diluting solvent, such as heptane for silicone oil. In operation 606, parylene is deposited, by CVD in a vacuum chamber, over the oil film. The deposited parylene grows dendrites from the surface, which is at the bottom of the oil film, through the oil to a top of the oil film. In operation 607, a solid layer of parylene is deposited/laid by further CVD on top of the oil film and dendrites. The solid layer cross polymerizes and binds to the tops of the dendrites, integrally connecting the solid layer with the dendrites.

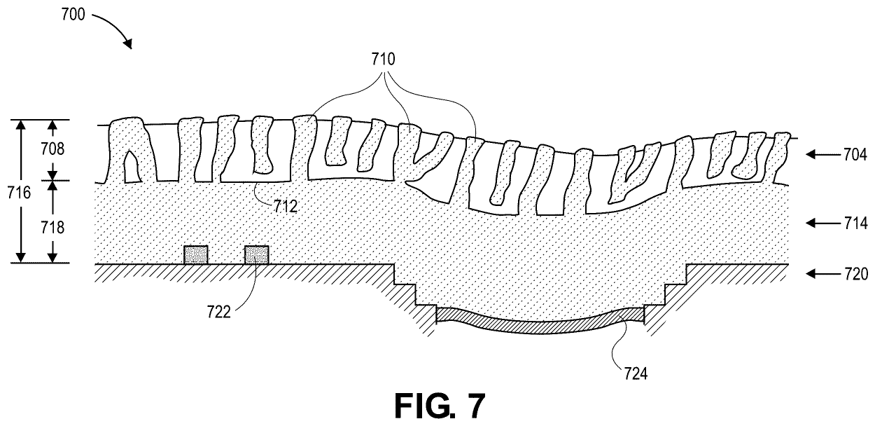

FIG. 7 is a cross section view of a water repellant, biofouling resistant coating 700 over device 720. Device 720 has metal traces 722 and recessed component 724.

Parylene-in-oil layer 704 has thickness 704, typically less-than-or-equal-to 10 μm. Conformal parylene layer 714 has thickness 718. Interface 712 is where the original layer of parylene conformal coating was on the device before oil was poured onto it. The combined thickness of the parylene-in-oil layer 704 and solid parylene layer 714 is coating thickness 716.

Dendrites 710, surrounded by oil, extend from conformal parylene layer 714, at the bottom of the oil film, through oil to the top of the oil film layer 704. Some dendrites do not extend all of the way through the oil film; some form branches.

The hydrophobic parylene-in-oil surface layer 704 is akin to a slippery liquid-infused porous surface (SLIPS) except that the subtractive step of forming porous structures on a substrate surface for in SLIPS is eliminated. No lithography is required.

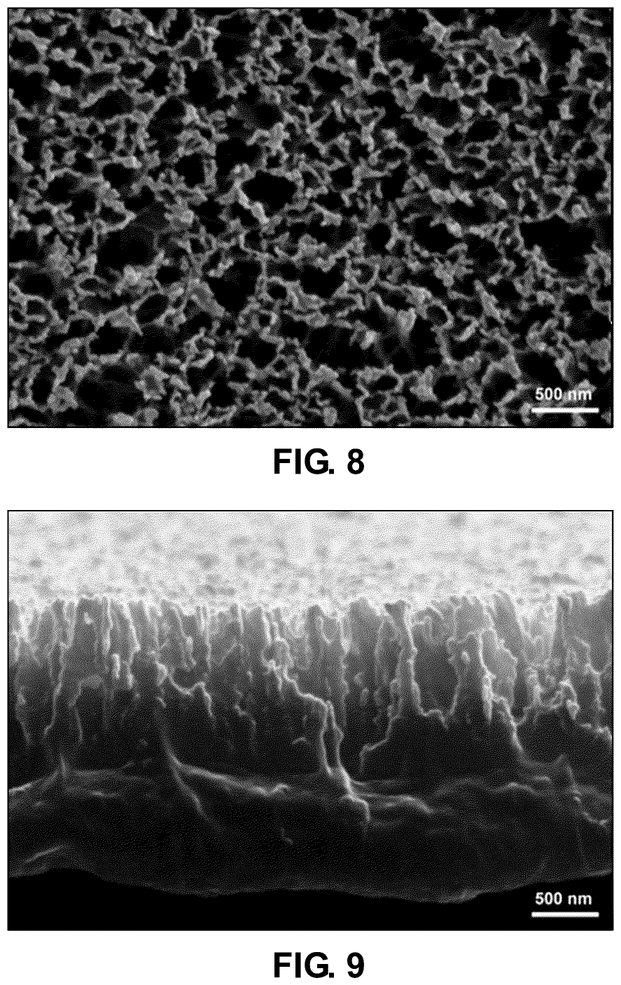

FIGS. 8-9 are SEM micrographs of the top and a cross section, respectively, of a biofouling resistant coating created using parylene C and 100,000 cSt silicone oil.

Measurements of the coating found that the parylene-in-oil portion of the coating had 30% porosity, an average pore size of 180±87 nanometers (nm) in diameter, and an average length of dendrites of 1.247±0.041 μm. Intriguingly, it also had a water contact angle of 150.30°±2.39°. Water and porcine blood droplets readily roll off a surface tilted at 8°.

“Superhydrophobicity” is typically defined as a combination of water contact angle (WCA) larger than 150° and sliding angle (SA) smaller than 10°. In this case, the water contact angle and sliding angle criteria are met, and so this coating is considered superhydrophobic.

In comparison, parylene C (only) was measured to have a water contact angle of 90.24°±2.54°. Silicone oil (only) was measured to have a water contact angle of 108.42°±2.84°. Remarkably, the combination of these materials in the parylene-in-oil manner described exhibited a drastic increase in water contact angle to 150.30°±2.39°. These unexpected results suggest that the combined effects of the porous parylene C structures and the infused silicone oil effectively altered the apparent surface energy to achieve superhydrophobicity.

Superhydrophobicity is often correlated with anti-biofouling surfaces, and so, as will be shown below, this water-repellant coating is sometimes simply referred to as a biofouling resistant coating.

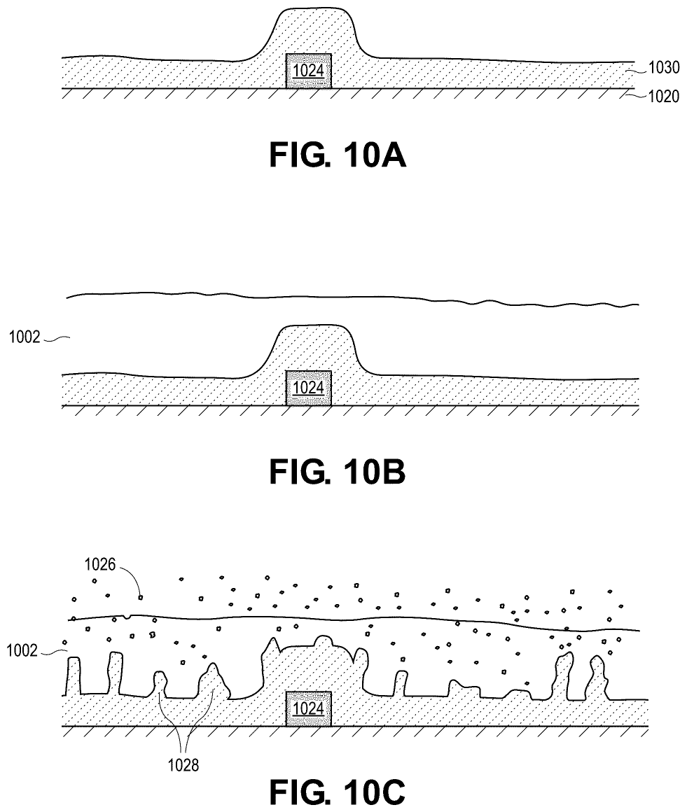

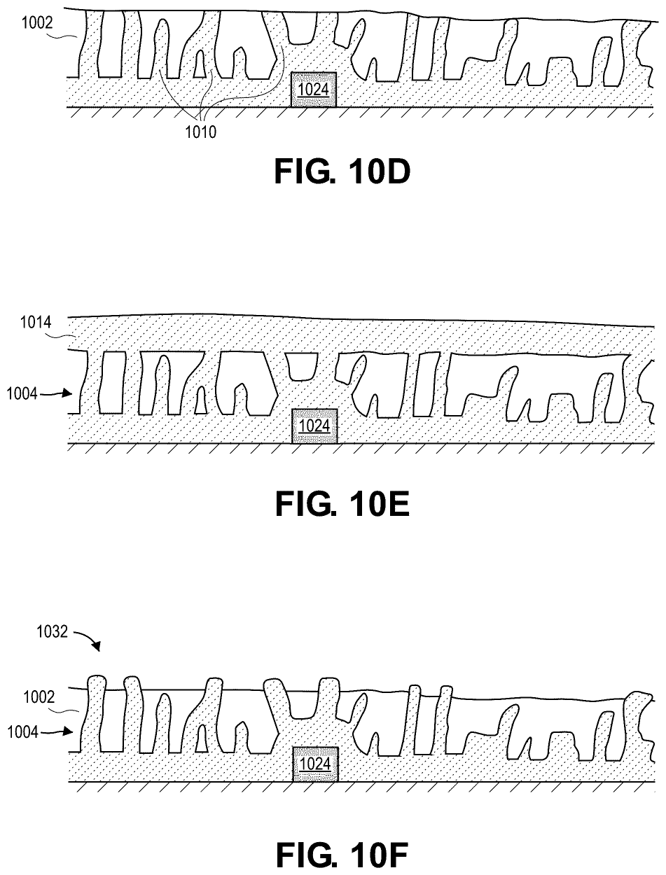

FIGS. 10A-10F illustrate the manufacture of a water-repellant coating over an electronic device in accordance with an embodiment.

In FIG. 10A, device 1020 with electronic component 1024 in conformally coated with conformal parylene 1030. In FIG. 10B, oil 1002 is applied onto the device.

In FIG. 10C, parylene is deposited, by chemical vapor deposition in a vacuum chamber, over oil film 1002. Superheated parylene monomers 1026 enter the room temperature deposition chamber and diffuse into oil 1002. The deposited parylene grows inchoate dendrites 1028 from the conformal surface 1030 (see FIG. 10A) up through oil 1002. In FIG. 10D, some parylene dendrites 1010 have grown all the way to the top of oil film 1002. CVD may stop temporarily or may continue without pause.

In FIG. 10E, solid parylene layer 1014 is laid, by CVD, on top of parylene-in-oil layer 1004. In total, 2 μm of parylene was deposited over the oil film.

In FIG. 10F, the solid layer is etched away, in this case by oxygen plasma at 200 mtorr (26.7 Pa), to remove the solid, bulk parylene and expose parylene-in-oil layer 1004. The etching process was self-limiting as the oxygen plasma hardly removed silicone oil.

The residual hydrophilic groups on the surface, mostly hydroxyl groups resulting from the oxygen plasma treatment, were removed by an 80° C. bake overnight to ensure hydrophobicity. In the end is biofouling-resistant coating 1032, the cross section of which is akin to that in FIG. 9.

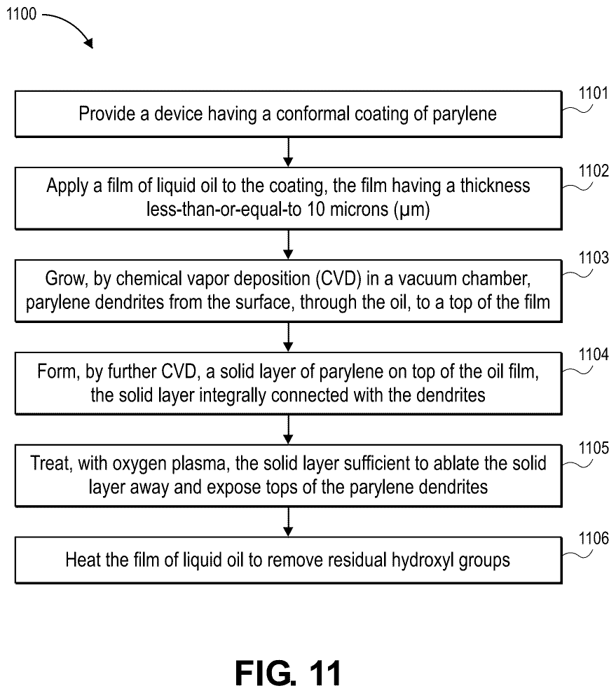

FIG. 11 is a flowchart illustrating process 1100 in accordance with an embodiment. In operation 1101, a device having a conformal coating of parylene is provided. In operation 1102, a film of liquid oil is applied to a surface of the coating, the film having a thickness less-than-or-equal-to 10 microns. In operation 1103, parylene dendrites are grown, by CVD in a vacuum chamber, from the surface, through the oil, to a top of the oil film. In operation 1104, a solid layer of parylene is formed, by further CVD, on top of the oil film. The solid layer integrally connects with the tops of the dendrites. In operation 1105, the solid layer is treated with oxygen plasma sufficient to etch/ablate the solid layer away and expose the tops of the parylene dendrites. In operation 1106, the film of liquid is heated in order to remove residual hydroxyl groups that were mostly left from the oxygen plasma treatment.

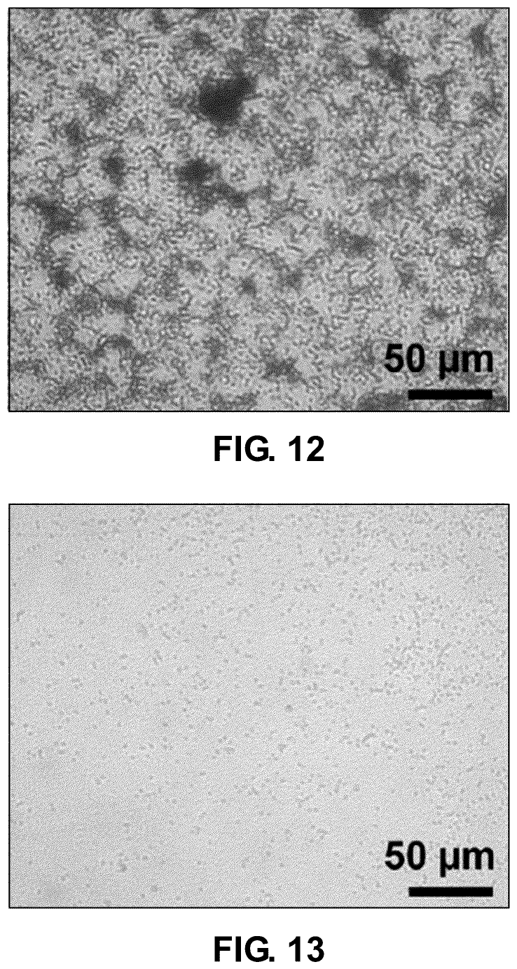

FIGS. 12-13 exemplify the biofouling resistance of the coating. For both micrographs, E. coli biofilms were seeded at a density of 2.4×10⁸ cells/mL over their respective coatings and then incubated for 24 hours at 37° C. Violet stain was applied for visibility of the cells. FIG. 12 is a micrograph of a standard, control coating of parylene C. FIG. 13 is a micrograph of the biofouling resistant coating. In comparison to the control coating, the biofouling resistant coating hardly shows any bacteria film at all.

The exposed parylene-in-oil surface significantly reduced the E. coli coating to only around 13% of the coverage area of the biofouling resistant coating surface, demonstrating its advantages in reducing E. coli fouling. The high mobility liquid surface of the parylene-in-oil posed extra difficulty for E. coli to adhere to the mobile surface. With the presence of parylene-in-oil, the cellular adherence mechanism of bacteria pili may be impaired, so the proliferation was also disrupted.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain. “About” in reference to a temperature or other engineering units includes measurements or settings that are within ±1%, ±2%, ±5%, ±10%, or other tolerances of the specified engineering units as known in the art.

The scope of protection is limited solely by the claims that now follow. That scope is intended and should be interpreted to be as broad as is consistent with the ordinary meaning of the language that is used in the claims when interpreted in light of this specification and the prosecution history that follows and to encompass all structural and functional equivalents.

Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements, but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. A composition of matter for hydrophobic coatings, the composition of matter comprising:
a film of liquid oil having a thickness less-than-or-equal-to 10 microns (μm); and
parylene dendrites extending through the oil film from one surface of the film to an opposing surface of the film.

2. The composition of matter of claim 1 wherein the oil has a vapor pressure of less than 1.333 kilopascals at 25° C.

3. The composition of matter of claim 1 wherein the oil is selected from the biocompatible group consisting of silicone oil, fluorinated oil, vegetable oil, and natural human fat oil.

4. The composition of matter of claim 1 wherein the oil is silicone oil with a viscosity greater-than-or-equal-to 10 centistokes (cSt).

5. The composition of matter of claim 4 wherein the film thickness is between 0.5 μm and 10 μm.

6. The composition of matter of claim 1 wherein the parylene is selected from the group consisting of parylene C, parylene D, parylene F, parylene AF-4, and parylene N.

7. The composition of matter of claim 1 further comprising:
a layer of solid parylene integrally formed with the parylene dendrites.

8. An apparatus with a biofouling-resistant coating, the apparatus comprising:
a device; and
the composition of matter of claim 7, wherein the layer of solid parylene is conformally coated on a surface of the device and the film of liquid oil with parylene dendrites faces outward.

9. An apparatus with a corrosion resistant coating, the apparatus comprising:
a device; and
the composition of matter of claim 7, wherein the film of liquid oil with parylene dendrites is conformally coated on a surface of the device and the layer of solid parylene faces outward.

10. The apparatus of claim 9 wherein the surface of the device includes metal traces or metal components for an electrical circuit.

11. A method of producing a coating that bestows corrosion-resistance to a surface, the method comprising:
providing a surface to be protected;
applying a film of liquid oil to the surface, the film having a thickness less-than-or-equal-to 10 microns (μm);
depositing, by chemical vapor deposition (CVD) in a vacuum chamber, parylene over the oil film, the deposited parylene growing dendrites from the surface, at the bottom of the oil film, through the oil to a top of the oil film; and
laying, by further CVD, a solid layer of parylene on top of the oil film and dendrites, the solid layer integrally connecting with the dendrites.

12. The method of claim 11 wherein the oil is selected from the biocompatible group consisting of silicone oil, fluorinated oil, vegetable oil, and natural human fat oil.

13. The method of claim 11 wherein the oil is silicone oil with a viscosity greater-than-or-equal-to 10 centistokes (cSt).

14. The method of claim 11 wherein the surface includes metal traces or metal components for an electrical circuit.

15. The method of claim 11 wherein the applying includes reducing the film thickness to between 1 μm and 2 μm.

16. The method of claim 11 wherein the applying includes spinning the surface in order to reduce the film thickness to less-than-or-equal-to 10 μm.

17. The method of claim 11 further comprising:
silanizing the surface before applying the film of liquid oil.

18. The method of claim 11 wherein the oil is initially diluted in a solvent, the method further comprising:
heating the film of liquid oil to evaporate the solvent after the applying.

19. The method of claim 11 wherein the parylene is selected from the group consisting of parylene C, parylene D, parylene F, parylene AF-4, and parylene N.

20. A method of producing a fluid-repellant, biofouling-resistant surface, the method comprising:
providing a device having a conformal coating of parylene;
applying a film of liquid oil to a surface of the coating, the film having a thickness less-than-or-equal-to 10 microns (μm);
growing, by chemical vapor deposition (CVD) in a vacuum chamber, parylene dendrites from the surface, through the oil, to a top of the film;
forming, by further CVD, a solid layer of parylene on top of the oil film, the solid layer integrally connected with the dendrites; and
treating, with oxygen plasma, the solid layer sufficient to ablate the solid layer away and expose tops of the parylene dendrites.
